(19) United States
(12) Patent Application Publication
(10) Pub. No.: US 2025/0336635 A1
(43) Pub. Date: Oct. 30, 2025

(54) CHARGED-PARTICLE BEAM APPARATUS WITH FAST FOCUS CORRECTION AND METHODS THEREOF

(71) Applicant: ASML Netherlands B.V., Veldhoven (NL)

(72) Inventors: Xiaoyu JI, San Jose, CA (US); Weiming REN, San Jose, CA (US); Wei-Yu CHANG, Tainan (TW)

(73) Assignee: ASML Netherlands B.V., Veldhoven (NL)

(21) Appl. No.: 18/871,563

(22) PCT Filed: May 10, 2023
(86) PCT No.: PCT/EP2023/062401

§ 371 Date: Dec. 4, 2024

Related U.S. Application Data
(60) Provisional application No. 63/351,273, filed on Jun. 10, 2022.

(51) Int. Cl. H01J 37/145; H01J 37/244; H01J 37/28

(52) U.S. Cl. CPC H01J 37/145; H01J 37/244; H01J 37/28; H01J 2237/2448

(57) ABSTRACT

Systems and methods of imaging a sample using a charged-particle beam apparatus are disclosed. The apparatus may include a charged-particle source configured to emit charged particles, the emitted charged particles forming a primary charged-particle beam along a primary optical axis; an objective lens comprising a magnetic lens; a charged-particle detector located downstream from the objective lens with respect to a path of the primary charged-particle beam and along a horizontal plane substantially perpendicular to the primary optical axis; and a voltage control plate located between the charged-particle detector and a pole-piece of the magnetic lens. The voltage control plate may comprise a horizontal portion comprising an opening; and an elongated portion extending downward from the opening with respect to the path of the primary charged-particle beam, into a hole of the charged-particle detector.

### CROSS-REFERENCE TO RELATED APPLICATIONS

This application claims priority of U.S. application 63/351,273 which was filed on 10 Jun. 2022 and which is incorporated herein in its entirety by reference.

### TECHNICAL FIELD

The embodiments provided herein disclose a charged-particle beam apparatus, and more particularly an electron beam inspection apparatus with fast focus adjustments to image three-dimensional (3D) structures on a substrate.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the complexity in device architecture increases, accurate inspection of 3D structures has become more important. Although high landing energy beams may be used to image structures of high aspect ratios and the focus of such high energy beams may be adjusted between the top and the bottom surface of the 3D structures, the focus adjustment techniques may interfere with the signal detection or signal collection by the charged-particle detector (e.g., a backscattered electron detector).

### SUMMARY

One aspect of the present disclosure is directed to a charged-particle beam apparatus to image a sample. The charged-particle beam apparatus may include a charged-particle source configured to emit charged particles, the emitted charged particles forming a primary charged-particle beam along a primary optical axis. The apparatus may further include an objective lens comprising a magnetic lens, a charged-particle detector located downstream from the objective lens with respect to a path of the primary charged-particle beam and along a horizontal plane substantially perpendicular to the primary optical axis, and a voltage control plate located between the charged-particle detector and a polepiece of the magnetic lens. The voltage control plate may include a horizontal portion comprising an opening and an elongated portion extending downward from the opening with respect to the path of the primary charged-particle beam, into a hole of the charged-particle detector.

Another aspect of the present disclosure is directed to a method for imaging a sample using a charged-particle beam apparatus. The method may include forming a primary charged-particle beam from charged particles emitted by a charged-particle source, detecting signal electrons generated from the sample upon interaction of the primary charged-particle beam with the sample using a charged-particle detector, adjusting an electrical signal applied to a voltage control plate. The voltage control plate may include a horizontal portion comprising an opening, and an elongated portion extending downward from the opening with respect to a path of the primary charged-particle beam, into a hole of the charged-particle detector.

Yet another aspect of the present disclosure is directed to a non-transitory computer readable medium storing a set of instructions that is executable by one or more processors of a charged-particle beam apparatus to cause the charged-particle beam apparatus to perform a method. The method may include forming a primary charged-particle beam from charged particles emitted by a charged-particle source, detecting signal electrons generated from the sample upon interaction of the primary charged-particle beam with the sample using a charged-particle detector, adjusting an electrical signal applied to a voltage control plate. The voltage control plate may include a horizontal portion comprising an opening, and an elongated portion extending downward from the opening with respect to a path of the primary charged-particle beam, into a hole of the charged-particle detector.

Yet another aspect of the present disclosure is directed to an electron-optical assembly. The electron-optical assembly may include an objective lens comprising a magnetic lens, a charged-particle detector located downstream from the objective lens with respect to a path of a primary charged-particle beam and along a horizontal plane substantially perpendicular to a primary optical axis, and a voltage control plate located between the charged-particle detector and a polepiece of the magnetic lens. The voltage control plate may include a horizontal portion comprising an opening and an elongated portion extending downward from the opening with respect to the path of the primary charged-particle beam, into a hole of the charged-particle detector, wherein the opening and the elongated portion form a cavity configured to allow the primary charged-particle beam to pass through.

Yet another aspect of this disclosure is directed to plate insertable between a charged-particle detector and a polepiece of an objective lens of a charged-particle beam apparatus. The plate may include a horizontal portion comprising an opening and an elongated portion extending downward from the opening with respect to the path of the primary charged-particle beam, into a hole of the charged-particle detector, wherein the opening and the elongated portion form a cavity configured to allow the primary charged-particle beam to pass through.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

FIG. 1 is a schematic diagram illustrating an exemplary electron beam inspection (EBI) system, consistent with embodiments of the present disclosure.

FIG. 2 is a schematic diagram illustrating an exemplary electron beam tool that can be a part of the exemplary electron beam inspection system of FIG. 1, consistent with embodiments of the present disclosure.

FIG. 3 is a schematic diagram of an exemplary charged-particle beam apparatus comprising a charged-particle detector, consistent with embodiments of the present disclosure.

FIG. 4 is a schematic diagram illustrating a portion of an exemplary charged-particle beam apparatus comprising a voltage control plate, consistent with embodiments of the present disclosure.

FIG. 5 is a schematic diagram illustrating a portion of an exemplary charged-particle beam apparatus comprising a voltage control plate, consistent with embodiments of the present disclosure.

FIG. 6A is schematic illustration of a top-view of an exemplary voltage control plate, consistent with embodiments of the present disclosure.

FIGS. 6B and 6C are schematic illustrations of a cross-sectional view along axis A-A′ (shown in FIG. 6A) of an exemplary voltage control plate, consistent with embodiments of the present disclosure.

FIG. 7 is a process flowchart representing an exemplary method of imaging a sample using a high landing-energy charged-particle beam in a charged-particle beam apparatus of FIG. 4 or 5, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC, thereby rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur.

In currently existing inspection systems, such as SEMs, 3D structures such as high aspect ratio (HAR) contact holes, may be imaged using an electron beam with high landing energy, among other things. For a given set of conditions, a higher landing-energy of the incident electrons may increase the interaction volume with the sample and generate more backscattered electrons, which may provide information associated with underlying features in the sample. However, focusing a high landing-energy electron beam to form high resolution images of a top and a bottom surface of such structures, while maintaining the accuracy of the measurement and the throughput, may be challenging.

In complex device architecture such as that of a 3D-NAND device, 3D structures, which may be several microns (μm) in depth, may be inspected or measured using high landing-energy beams. The interaction volume, and therefore the backscattered signal electron intensity, may be enhanced by using high landing-energy electron beams. However, adjusting the focal length of the high landing-energy electron beam to image the top and the bottom surfaces of the 3D structures may render the inspection process significantly longer compared to the inspection of two-dimensional planar structures. In some instances, while the focus of the high landing-energy electron beams may be adjusted or corrected by applying voltage signals to the electrostatic lenses, the focal length adjustment per unit voltage applied may be undesirably small. In other words, a very large voltage signal may be applied to cause a small adjustment in the focal length of the high landing-energy beam. A large voltage signal applied to the electrostatic lens may negatively affect the detection efficiency of a backscattered electron detector, among other things, thereby impacting the inspection throughput.

One of several ways to realize focus adjustment for imaging 3D structures includes concurrently using an electron detector as an electrode to adjust the electrostatic field in the vicinity of the sample, thereby adjusting the focal length of the primary electron beam. Such a configuration, however, may have several disadvantages. For example, the voltage signal applied to the electron detector to adjust the electrostatic field may change the landing energy of the backscattered electrons it is primarily configured to detect. A change in the applied voltage to the electron detector may further affect the photon emission intensity of, for example, a scintillator, thereby producing low quality images and resulting in inaccurate inspection and measurement of the imaged structures. Further, in such a configuration, a build-up of charges or contaminants on the inner surfaces of the central hole of the backscattered electron detector may impact the rotational symmetry and smoothness, which may induce higher order electric fields such as quadrupole fields. The higher order fields may interfere with the electrostatic field experienced by the primary electron beam and may negatively affect the probe spot size or probe spot shape. Although the inner surface of the backscattered electron detector may be cleaned, polishing the inner surface to maintain the smoothness may be challenging. In comparison, the voltage control plate is configurable to provide a superior inner surface by, for example, reworking, polishing or cleaning its inner surface. The build-up of charges or contaminants on the inner surfaces of the central hole of the backscattered electron detector may impact the rotational symmetry and smoothness, which may induce higher order electric fields such as quadrupole fields. The higher order fields may interfere with the electrostatic field experienced by the primary electron beam and may negatively affect the probe spot size or probe spot shape. The ability to clean or polish the inner surface of the voltage control plate allows, in addition to a smooth surface, retention of the ellipticity of the inner surface, thereby allowing obtaining high quality images reliably while maintaining the throughput. The voltage control plate may be an insertable plate made from an electrically conducting material such as a metal, or a non-magnetic material. Therefore, while the dual functionality of the electron detector may improve the inspection throughput, the quality of images produced may be impacted, rendering the inspection system inadequate. It may thus be desirable to achieve focus-correction of high landing-energy electron beams to inspect the top and the bottom surfaces of 3D structures, while maintaining the resolution and throughput of the SEM and the electron detection capabilities of the detector.

Some embodiments of the present disclosure are directed to apparatuses and methods of imaging a sample with high landing-energy charged-particle beams. The apparatus may include a voltage control plate located between a backscattered electron detector and a polepiece of a magnetic lens of a compound objective lens. The voltage control plate may comprise a horizontal portion having an aperture and an elongated portion extending downward from the aperture into a central hole of the backscattered electron detector. The voltage control plate may include a cavity formed by the inner surfaces of the aperture and the elongated portion. The voltage control plate may be configured to receive a voltage signal which, when applied or adjusted, may influence the electrostatic field experienced by the primary electron beam passing through the cavity, thereby adjusting the focal length of the primary electron beam to be incident on the sample. The focal length of the primary electron beam may be adjusted using a voltage control plate without interfering with the backscattered collection efficiency, thus enabling high imaging quality while maintaining inspection and measurement accuracy and throughput.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

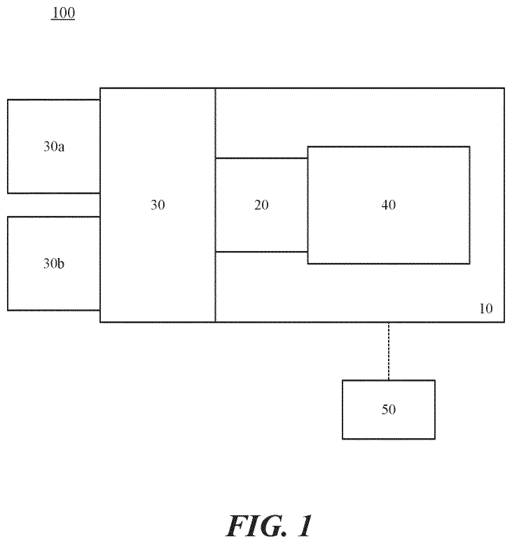

Reference is now made to FIG. 1, which illustrates an exemplary electron beam inspection (EBI) system 100 consistent with embodiments of the present disclosure. As shown in FIG. 1, charged particle beam inspection system 100 includes a main chamber 10, a load-lock chamber 20, an electron beam tool 40, and an equipment front end module (EFEM) 30. Electron beam tool 40 is located within main chamber 10. While the description and drawings are directed to an electron beam, it is appreciated that the embodiments are not used to limit the present disclosure to specific charged particles.

EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (not shown) in EFEM 30 transport the wafers to load-lock chamber 20.

Load-lock chamber 20 is connected to a load/lock vacuum pump system (not shown), which removes gas molecules in load-lock chamber 20 to reach a first pressure below the atmospheric pressure. After reaching the first pressure, one or more robot arms (not shown) transport the wafer from load-lock chamber 20 to main chamber 10. Main chamber 10 is connected to a main chamber vacuum pump system (not shown), which removes gas molecules in main chamber 10 to reach a second pressure below the first pressure. After reaching the second pressure, the wafer is subject to inspection by electron beam tool 40. In some embodiments, electron beam tool 40 may comprise a single-beam inspection tool. In other embodiments, electron beam tool 40 may comprise a multi-beam inspection tool.

Controller 50 may be electronically connected to electron beam tool 40 and may be electronically connected to other components as well. Controller 50 may be a computer configured to execute various controls of charged particle beam inspection system 100. Controller 50 may also include processing circuitry configured to execute various signal and image processing functions. While controller 50 is shown in FIG. 1 as being outside of the structure that includes main chamber 10, load-lock chamber 20, and EFEM 30, it is appreciated that controller 50 can be part of the structure.

While the present disclosure provides examples of main chamber 10 housing an electron beam inspection system, it should be noted that aspects of the disclosure in their broadest sense, are not limited to a chamber housing an electron beam inspection system. Rather, it is appreciated that the foregoing principles may be applied to other chambers as well.

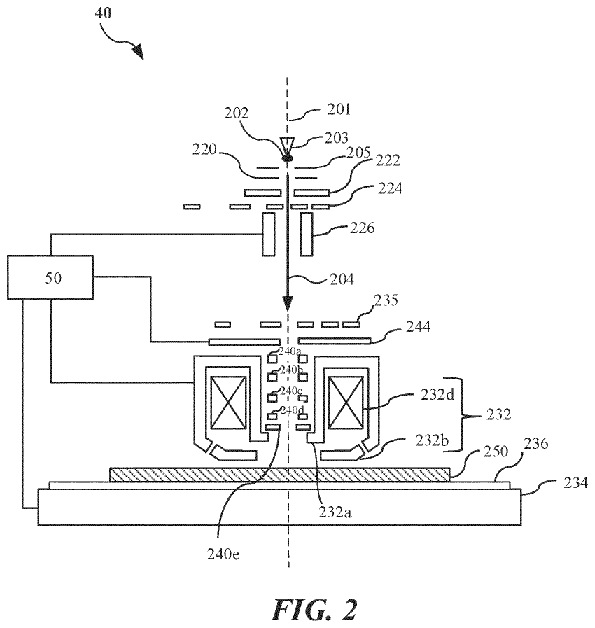

Reference is now made to FIG. 2, which illustrates a schematic diagram illustrating an exemplary configuration of electron beam tool 40 that can be a part of the exemplary charged particle beam inspection system 100 of FIG. 1, consistent with embodiments of the present disclosure. Electron beam tool 40 (also referred to herein as apparatus 40) may comprise an electron emitter, which may comprise a cathode 203, an extractor electrode 205, a gun aperture 220, and an anode 222. Electron beam tool 40 may further include a Coulomb aperture array 224, a condenser lens 226, a beam-limiting aperture array 235, an objective lens assembly 232, and an electron detector 244. Electron beam tool 40 may further include a sample holder 236 supported by motorized stage 234 to hold a sample 250 to be inspected. It is to be appreciated that other relevant components may be added or omitted, as needed.

In some embodiments, electron emitter may include cathode 203, an anode 222, wherein primary electrons can be emitted from the cathode and extracted or accelerated to form a primary electron beam 204 that forms a primary beam crossover 202. Primary electron beam 204 can be visualized as being emitted from primary beam crossover 202.

In some embodiments, the electron emitter, condenser lens 226, objective lens assembly 232, beam-limiting aperture array 235, and electron detector 244 may be aligned with a primary optical axis 201 of apparatus 40. In some embodiments, electron detector 244 may be placed off primary optical axis 201, along a secondary optical axis (not shown).

Objective lens assembly 232, in some embodiments, may comprise a modified swing objective retarding immersion lens (SORIL), which includes a pole piece 232a, a control electrode 232b, a beam manipulator assembly comprising deflectors 240a, 240b, 240d, and 240e, and an exciting coil 232d. In a general imaging process, primary electron beam 204 emanating from the tip of cathode 203 is accelerated by an accelerating voltage applied to anode 222. A portion of primary electron beam 204 passes through gun aperture 220, and an aperture of Coulomb aperture array 224, and is focused by condenser lens 226 so as to fully or partially pass through an aperture of beam-limiting aperture array 235. The electrons passing through the aperture of beam-limiting aperture array 235 may be focused to form a probe spot on the surface of sample 250 by the modified SORIL lens and deflected to scan the surface of sample 250 by one or more deflectors of the beam manipulator assembly. Secondary electrons emanated from the sample surface may be collected by electron detector 244 to form an image of the scanned area of interest.

In objective lens assembly 232, exciting coil 232d and pole piece 232a may generate a magnetic field. A part of sample 250 being scanned by primary electron beam 204 can be immersed in the magnetic field and can be electrically charged, which, in turn, creates an electric field. The electric field may reduce the energy of impinging primary electron beam 204 near and on the surface of sample 250. Control electrode 232b, being electrically isolated from pole piece 232a, may control, for example, an electric field above and on sample 250 to reduce aberrations of objective lens assembly 232 and control focusing situation of signal electron beams for high detection efficiency, or avoid arcing to protect sample. One or more deflectors of beam manipulator assembly may deflect primary electron beam 204 to facilitate beam scanning on sample 250. For example, in a scanning process, deflectors 240a, 240b, 240d, and 240e can be controlled to deflect primary electron beam 204, onto different locations of top surface of sample 250 at different time points, to provide data for image reconstruction for different parts of sample 250. It is noted that the order of 240a-e may be different in different embodiments.

Backscattered electrons (BSEs) and secondary electrons (SEs) can be emitted from the part of sample 250 upon receiving primary electron beam 204. A beam separator can direct the secondary or scattered electron beam(s), comprising backscattered and secondary electrons, to a sensor surface of electron detector 244. The detected secondary electron beams can form corresponding beam spots on the sensor surface of electron detector 244. Electron detector 244 can generate signals (e.g., voltages, currents) that represent the intensities of the received secondary electron beam spots, and provide the signals to a processing system, such as controller 50. The intensity of secondary or backscattered electron beams, and the resultant secondary electron beam spots, can vary according to the external or internal structure of sample 250. Moreover, as discussed above, primary electron beam 204 can be deflected onto different locations of the top surface of sample 250 to generate secondary or scattered electron beams (and the resultant beam spots) of different intensities. Therefore, by mapping the intensities of the secondary electron beam spots with the locations of sample 250, the processing system can reconstruct an image that reflects the internal or external structures of wafer sample 250.

In some embodiments, controller 50 may comprise an image processing system that includes an image acquirer (not shown) and a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detector 244 of apparatus 40 through a medium such as an electrical conductor, optical fiber cable, portable storage media, IR, Bluetooth, internet, wireless network, wireless radio, among others, or a combination thereof. In some embodiments, the image acquirer may receive a signal from electron detector 244 and may construct an image. The image acquirer may thus acquire images of regions of sample 250. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, controller 50 may include measurement circuitries (e.g., analog-to-digital converters) to obtain a distribution of the detected secondary electrons and backscattered electrons. The electron distribution data collected during a detection time window, in combination with corresponding scan path data of a primary beam 204 incident on the sample (e.g., a wafer) surface, can be used to reconstruct images of the wafer structures under inspection. The reconstructed images can be used to reveal various features of the internal or external structures of sample 250, and thereby can be used to reveal any defects that may exist in the wafer.

In some embodiments, controller 50 may control motorized stage 234 to move sample 250 during inspection. In some embodiments, controller 50 may enable motorized stage 234 to move sample 250 in a direction continuously at a constant speed. In other embodiments, controller 50 may enable motorized stage 234 to change the speed of the movement of sample 250 over time depending on the steps of scanning process.

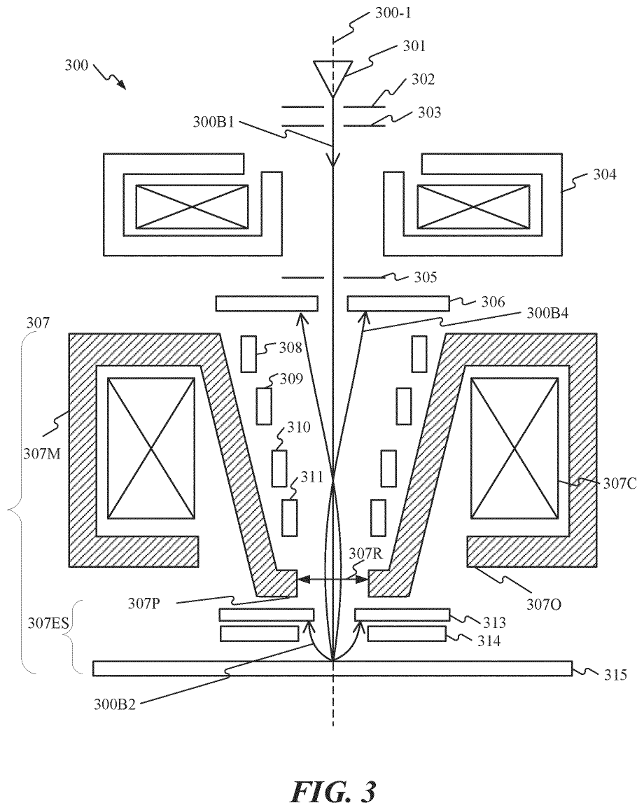

Reference is now made to FIG. 3, which illustrates a schematic diagram of an exemplary charged-particle beam apparatus 300 (also referred to as apparatus 300), consistent with embodiments of the present disclosure. Apparatus 300 may include a charged-particle source such as, an electron source configured to emit primary electrons from a cathode 301 and extracted using an extractor electrode 302 to form a primary electron beam 300B1 along a primary optical axis 300-1. Apparatus 300 may further comprise an anode 303, a condenser lens 304, a beam-limiting aperture array 305, signal electron detectors 306 and 313, a compound objective lens 307, a scanning deflection unit comprising primary electron beam deflectors 308, 309, 310, and 311, and a control electrode 314. In some embodiments, signal electron detector 313 may be a backscattered electron detector, and signal electron detector 306 may be a secondary electron detector. It is to be appreciated that relevant components may be added, omitted, or reordered, as appropriate.

An electron source (not shown) may include a thermionic source configured to emit electrons upon being supplied thermal energy to overcome the work function of the source, a field emission source configured to emit electrons upon being exposed to a large electrostatic field, etc. In the case of a field emission source, the electron source may be electrically connected to a controller, such as controller 50 of FIG. 2, configured to apply and adjust a voltage signal based on a desired landing energy, sample analysis, source characteristics, among other things. Extractor electrode 302 may be configured to extract or accelerate electrons emitted from a field emission gun, for example, to form primary electron beam 300B1 that forms a virtual or a real primary beam crossover (not illustrated) along primary optical axis 300-1. Primary electron beam 300B1 may be visualized as being emitted from the primary beam crossover. In some embodiments, controller 50 may be configured to apply and adjust a voltage signal to extractor electrode 302 to extract or accelerate electrons generated from electron source. An amplitude of the voltage signal applied to extractor electrode 302 may be different from the amplitude of the voltage signal applied to cathode 301. In some embodiments, the difference between the amplitudes of the voltage signal applied to extractor electrode 302 and to cathode 301 may be configured to accelerate the electrons downstream along primary optical axis 300-1 while maintaining the stability of the electron source. As used in the context of this disclosure, “downstream” refers to a direction along the path of primary electron beam 300B1 starting from the electron source towards sample 315. With reference to positioning of an element of a charged-particle beam apparatus (e.g., apparatus 300 of FIG. 3), “downstream” may refer to a position of an element located below or after another element, along the path of primary electron beam starting from the electron source, and “immediately downstream” refers to a position of a second element below or after a first element along the path of primary electron beam 300B1 such that there are no other active elements between the first and the second element. For example, as illustrated in FIG. 3, signal electron detector 306 may be positioned immediately downstream of beam-limiting aperture array 305 such that there are no other optical or electron-optical elements placed between beam-limiting aperture array 305 and electron detector 306. As used in the context of this disclosure, “upstream” may refer to a position of an element located above or before another element, along the path of primary electron beam starting from the electron source, and “immediately upstream” refers to a position of a second element above or before a first element along the path of primary electron beam 300B1 such that there are no other active elements between the first and the second element. As used herein, “active element” may refer to any element or component, the presence of which may modify the electrostatic or electromagnetic field between the first and the second element, either by generating an electric field, a magnetic field, or an electromagnetic field.

Apparatus 300 may comprise condenser lens 304 configured to receive a portion of or a substantial portion of primary electron beam 300B1 and to focus primary electron beam 300B1 on beam-limiting aperture array 305. Condenser lens 304 may be substantially similar to condenser lens 226 of FIG. 2 and may perform substantially similar functions. Although shown as a magnetic lens in FIG. 3, condenser lens 304 may be an electrostatic, a magnetic, an electromagnetic, or a compound electromagnetic lens, among others. Condenser lens 304 may be electrically coupled with controller 50, as illustrated in FIG. 2. Controller 50 may apply an electrical excitation signal to condenser lens 304 to adjust the focusing power of condenser lens 304 based on factors including, but are not limited to, operation mode, application, desired analysis, sample material being inspected, among other things.

Apparatus 300 may further comprise beam-limiting aperture array 305 configured to limit beam current of primary electron beam 300B1 passing through one of a plurality of beam-limiting apertures of beam-limiting aperture array 305. Although, only one beam-limiting aperture is illustrated in FIG. 3, beam-limiting aperture array 305 may include any number of apertures having uniform or non-uniform aperture size, cross-section, or pitch. In some embodiments, beam-limiting aperture array 305 may be disposed downstream of condenser lens 304 or immediately downstream of condenser lens 304 (as illustrated in FIG. 3) and substantially perpendicular to primary optical axis 300-1. In some embodiments, beam-limiting aperture array 305 may be configured as an electrically conducting structure comprising a plurality of beam-limiting apertures. Beam-limiting aperture array 305 may be electrically connected via a connector (not illustrated) with controller 50, which may be configured to instruct that a voltage be supplied to beam-limiting aperture array 305. The supplied voltage may be a reference voltage such as, for example, ground potential. Controller 50 may also be configured to maintain or adjust the supplied voltage. Controller 50 may be configured to adjust the position of beam-limiting aperture array 305.

Apparatus 300 may comprise one or more signal electron detectors 306 and 313. Interaction of the primary charged particles such as electrons of primary electron beam 300B1 with a surface of sample 315 may generate signal electrons. The signal electrons may include secondary electrons, backscattered electrons, or auger electrons, among other things. Signal electron detectors 306 and 313 may be configured to detect substantially all secondary electrons and a portion of backscattered electrons based on the emission energy or emission angle, among other things. In some embodiments, signal electron detectors 306 and 313 may be configured to detect secondary electrons, backscattered electrons, or auger electrons. Signal electron detector 313 may be disposed downstream of signal electron detector 306. In some embodiments, signal electron detector 313 may be disposed downstream from objective lens 307. Signal electrons having low emission energy (typically <50 eV) may comprise secondary electron beam(s) 300B4, and signal electrons having high emission energy (typically >50 eV) may comprise backscattered electron beam(s) 300B2. In some embodiments, 300B4 may comprise secondary electrons, low-energy backscattered electrons, or high-energy backscattered electrons. It is appreciated that although not illustrated, a portion of backscattered electrons may be detected by signal electron detector 306, and a portion of secondary electrons may be detected by signal electron detector 313. In inspection of 3D structures such as deep holes, grooves, or contact holes, a high landing-energy primary electron beam may be used, which generates signal electrons having high emission energy. Signal electron detector 313 may be used to detect a portion of high emission-energy signal electrons such as backscattered electrons.

Apparatus 300 may further include compound objective lens 307 configured to focus primary electron beam 300B1 on a surface of sample 315. Controller 50 may apply an electrical excitation signal to the coils 307C of compound objective lens 307 to adjust the focusing power of compound objective lens 307 based on factors including, but are not limited to, primary beam energy, application, desired analysis, sample material being inspected, among other things. Compound objective lens 307 may be further configured to focus signal electrons, such as secondary electrons or backscattered electrons on a detection surface of a signal electron detector (e.g., signal electron detectors 306 or 313). Compound objective lens 307 may be substantially similar to or perform substantially similar functions as objective lens assembly 232 of FIG. 2. In some embodiments, compound objective lens 307 may comprise an electromagnetic lens including a magnetic lens 307M, and an electrostatic lens 307ES formed by control electrode 314, polepiece 307P, and sample 315.

As used herein, a compound objective lens is an objective lens producing overlapping magnetic and electrostatic fields, both in the vicinity of the sample for focusing the primary electron beam. In this disclosure, though condenser lens 304 may also be a magnetic lens, a reference to a magnetic lens, such as 307M, refers to an objective magnetic lens, and a reference to an electrostatic lens, such as 307ES, refers to an objective electrostatic lens. As illustrated in FIG. 3, magnetic lens 307M and electrostatic lens 307ES, working in unison, for example, to focus primary electron beam 300B1 on sample 315, may form compound objective lens 307. The lens body of magnetic lens 307M and coil 307C may produce the magnetic field, while the electrostatic field may be produced by creating a potential difference, for example, between sample 315, and polepiece 307P. In some embodiments, control electrode 314 or other electrodes located between polepiece 307P and sample 315, may also be a part of electrostatic lens 307ES.

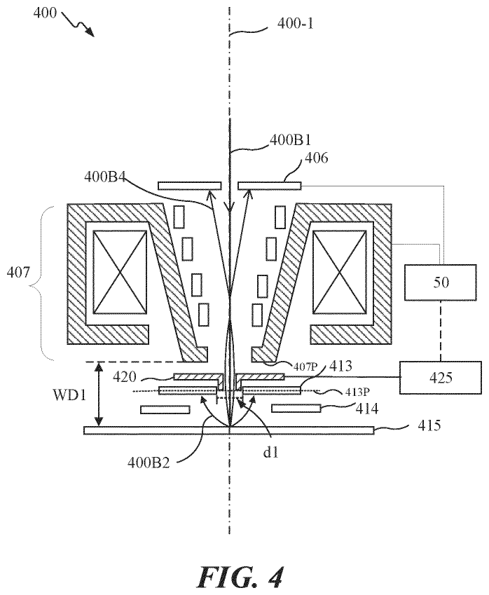

As disclosed herein, a polepiece of a magnetic lens (e.g., magnetic lens 307M) is a piece of magnetic material near the magnetic poles of a magnetic lens, while a magnetic pole is the end of the magnetic material where the external magnetic field is the strongest. As illustrated in FIG. 3, apparatus 300 comprises polepieces 307P and 307O. As an example, polepiece 307P may be the piece of magnetic material near the north pole of magnetic lens 307M, and polepiece 307O may be the piece of magnetic material near the south pole of magnetic lens 307M. When the current in magnetic lens coil 307C changes directions, the polarity of the magnetic poles may also change. In the context of this disclosure, the positioning of electron detectors (e.g., signal electron detector 313 of FIG. 3, or signal electron detector 413 of FIG. 4), beam deflectors (e.g., beam deflectors 308-311 of FIG. 3), electrodes (e.g., control electrode 314 of FIG. 3) may be described with reference to the position of polepiece 307P located closest to the point where primary optical axis 300-1 intersects sample 315. Polepiece 307P of magnetic lens 307M may comprise a magnetic pole made of a soft magnetic material, such as electromagnetic iron, which concentrates the magnetic field substantially within the cavity of magnetic lens 307M. Polepieces 307P and 307O may be high-resolution polepieces, multiuse polepieces, or high-contrast polepieces, for example.

As illustrated in FIG. 3, polepiece 307P may comprise an opening 307R configured to allow primary electron beam 300B1 to pass through and allow signal electrons to reach signal electron detector 306. Opening 307R of polepiece 307P may be circular, substantially circular, or non-circular in cross-section. In some embodiments, the geometric center of opening 307R of polepiece 307P may be aligned with primary optical axis 300-1. In some embodiments, as illustrated in FIG. 3, polepiece 307P may be the furthest downstream horizontal section of magnetic lens 307M and may be substantially perpendicular to primary optical axis 300-1. Polepieces (e.g., 307P and 307O) are one of several distinguishing features of magnetic lens over electrostatic lens. Because polepieces are magnetic components adjacent to the magnetic poles of a magnetic lens, and because electrostatic lenses do not produce a magnetic field, electrostatic lenses do not have polepieces.

Apparatus 300 may further include a scanning deflection unit comprising primary electron beam deflectors 308, 309, 310, and 311, configured to dynamically deflect primary electron beam 300B1 on a surface of sample 315. In some embodiments, scanning deflection unit comprising primary electron beam deflectors 308, 309, 310, and 311 may be referred to as a beam manipulator or a beam manipulator assembly. The dynamic deflection of primary electron beam 300B1 may cause a desired area or a desired region of interest of sample 315 to be scanned, for example in a raster scan pattern, to generate SEs and BSEs for sample inspection. One or more primary electron beam deflectors 308, 309, 310, and 311 may be configured to deflect primary electron beam 300B1 in X-axis or Y-axis, or a combination of X- and Y-axes. As used herein, X-axis and Y-axis form Cartesian coordinates, and primary electron beam 300B1 propagates along Z-axis or primary optical axis 300-1.

With the increasing demand in data processing and computing power of electronic devices, integrated circuit (IC) chips are required to perform more complex tasks with higher speed and higher efficiency. These requirements necessitate an increase in the device density (number of devices per unit area of a wafer), which may be achieved by fabricating 3D structures, among other strategies. While the 3D structures may be inspected using high landing-energy charged-particle beams, the speed of adjusting the focus to image the top and the bottom surface of the 3D structures may limit the throughput, rendering the apparatus inadequate for inspection or metrology applications. Although a backscattered electron detector, located close to the sample and configured to detect high emission-energy signal electrons, may also be used as an electrode to control the electrostatic field experienced by the primary electron beam, however, doing so may vary the landing energy of backscattered electrons on a detection surface of the backscattered electron detector, thereby negatively impacting the detector gain or the detector collection efficiency. Therefore, it may be desirable to control the electrostatic field to adjust the focal length of the high landing-energy electron beam without impacting the backscattered electron detector collection efficiency to obtain high resolution images while maintaining the throughput.

Reference is now made to FIG. 4, which illustrates a schematic diagram of a portion an exemplary charged-particle beam apparatus 400 (also referred to as apparatus 400), consistent with embodiments of the present disclosure. In comparison to apparatus 300, apparatus 400 may additionally include a voltage control plate 420. Apparatus 400 may further include a backscattered electron detector 413 (analogous to signal electron detectors 313 of FIG. 3) and a control electrode 414 (analogous to control electrode 314 of FIG. 3).

Backscattered electrons (BSEs) (e.g., signal electrons of beam 400B2) may be generated by elastic scattering events of the incident electrons from the underlying deeper layers, such as bottom surfaces of deep trenches or high aspect-ratio holes and have high emission energy—between 50 eV and incident energy of primary electron beam. Therefore, it may be desirable to maintain high backscattered electron detection efficiency to obtain high quality imaging of 3D structures. In some embodiments, apparatus 400 may include a signal electron detector such as backscattered electron detector 413 located between sample 415 and objective lens 407. Backscattered electron detector 413 may be positioned along a plane 413P substantially perpendicular to primary optical axis 400-1. It is appreciated that horizontal plane 413P along which backscattered electron detector 413 extends, represented by a broken line (dash-dash line), is an imaginary plane for visual aid and illustrative purposes only. Plane 413P represents a central plane of backscattered electron detector 413 with respect to a thickness of backscattered electron detector 413 in a direction parallel to primary optical axis 400-1. In the context of this disclosure, the term “substantially perpendicular” refers to a positioning of an element such that the element is sufficiently perpendicular with a negligible offset, if any, which does not negatively impact the intended function and expected performance of the element. As an example, a substantially perpendicular backscattered electron detector 413 may form 90°±0.05° with the primary optical axis 400-1, such that the orientation of backscattered electron detector 413 may not affect its detection efficiency, for example. The backscattered electron detector may form an angle between 89.95° and 90.05° with primary optical axis 400-1 such that the electrostatic field is unaffected. A larger offset, e.g., 0.1° or more from 90°, in the angle between the backscattered electron detector (e.g., backscattered electron detector 413) and primary optical axis (e.g., primary optical axis 400-1) may generate additional deflection field, which may cause the primary electron beam to shift and enlarge the landing angle, negatively impacting the resolution of the generated images therefrom.

In some embodiments, backscattered electron detector 413 may comprise a central hole aligned with primary optical axis 400-1. As illustrated in FIG. 4, the central hole of backscattered electron detector 413 may have an inner diameter d1. In some embodiments, inner diameter d1 of backscattered electron detector 413 may be smaller than the diameter of the opening (e.g., opening 307R of FIG. 3) of objective lens 407 (analogous to objective lens 307 of FIG. 3). In some embodiments, however, the inner diameter d1 may be determined based on factors including, but not limited to, field-of-view (FOV), working distance of the apparatus, resolution requirements, mechanical limitations, or physical space constraints, among other things.

Apparatus 400 may further comprise voltage control plate 420. In some embodiments, voltage control plate 420 may be an electrically conducting element configured to receive an electrical signal. In some embodiments, voltage control plate 420 may be made from a non-magnetic material. Voltage control plate 420 may be electrically connected to a voltage control unit 425, or controller 50, or both. Voltage control unit 425 or controller 50 may include circuitry configured to apply an electrical signal, such as a voltage signal to voltage control plate 420. Voltage control unit 425 or controller 50 may further include circuitry configured to adjust the applied electrical signal. Adjusting the applied electrical signal may include adjusting the voltage such that an electrostatic field experienced by the primary electrons passing through may be adjusted, resultantly adjusting a focal length of the primary electron beam to be incident on a surface of sample 415.

In some embodiments, voltage control plate 420 may be fabricated using an electrically conducting material such as a metal, among other things. Voltage control plate 420 may be located downstream from polepiece 407P of objective lens 407 and upstream from backscattered electron detector 413 with respect to a path of primary electron beam 400B1 along primary optical axis 400-1. Voltage control plate 420 may be positioned along a plane substantially perpendicular to primary optical axis 400-1 and substantially parallel to horizontal plane 413P. It is to be appreciated that objective lens 407 may be a compound objective lens comprising a magnetic lens and an electrostatic lens, and that a polepiece (e.g., polepiece 407P) refers to a polepiece of magnetic lens of objective lens 407.

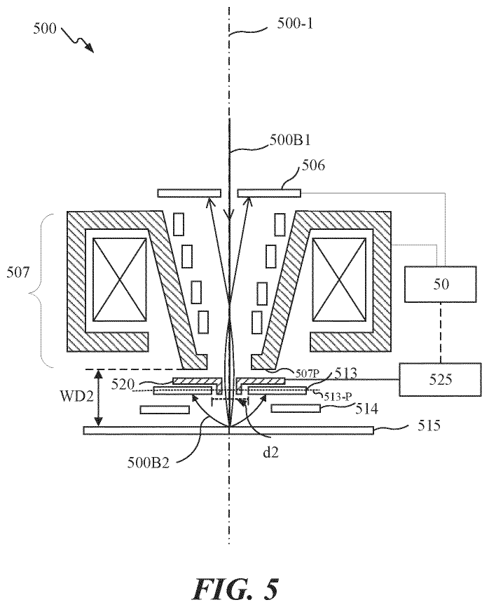

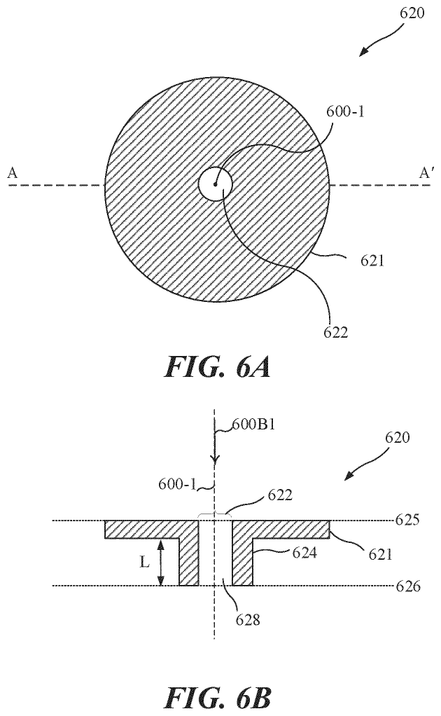

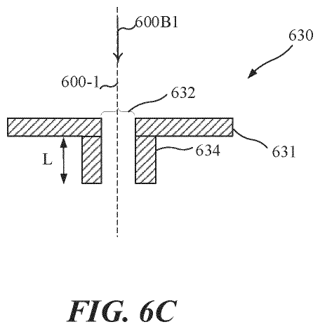

FIG. 6A illustrates a top view of an exemplary voltage control plate 620, analogous to voltage control plate 420. Voltage control plate 620 may include an opening 622 aligned with primary optical axis 600-1. As used herein, the term “aligned” refers to a positioning of voltage control plate 620 such that the geometric center of opening 622 coincides with primary optical axis 600-1. In some embodiments, as illustrated in FIG. 4 and FIG. 5 (discussed later), a diameter of opening 622 of voltage control plate 620 may be smaller than the diameter of the hole of backscattered electron detector 413, but large enough to allow primary electron beam 400B1 and secondary electron beam 400B4 to pass through, without blocking or hindering the path of primary or secondary electrons. Voltage control plate 620 may be made from a monolithic piece of material such as, but not limited to, a metal or other electrically conducting material. For example, voltage control plate 620 may be made from a single, continuous sheet of metal and opening 622 may be formed by removing the metal from the corresponding location. Opening 622 may be formed in a horizontal portion 621 by a material removal process including, but not limited to, etching, cutting, drilling, punching, among other material removal techniques. In some embodiments, although not shown, two or more pieces of an electrically conducting material may be attached together to form voltage control plate 620 comprising opening 622 having a desired diameter.

FIG. 6B illustrates a cross-section view of voltage control plate 620 along axis A-A′ (shown in FIG. 6A). As illustrated in FIG. 6B, voltage control plate 620 may further comprise a vertically elongated portion 624 extending downward from opening 622 along primary optical axis 600-1 and substantially perpendicular to horizontal portion 621 of voltage control plate 620. Elongated portion 624 may be substantially parallel to primary optical axis 600-1 along which primary electron beam 600B1 travels towards the sample (e.g., sample 415 of FIG. 4). The direction of travel of primary electron beam 600B1 is indicated by a solid arrow in FIG. 6B. Elongated portion 624 may have an inner diameter substantially similar to the diameter of opening 622. Elongated portion 624 may be cylindrical such that its inner diameter is uniform through its length L and similar to the diameter of opening 622. In such a configuration, opening 622 and elongated portion 624 may form a cavity 628 having a diameter substantially similar to the diameter of opening 622, for the primary and secondary electrons to pass through. Cavity 628 may be defined by the space between imaginary planes 625 and 626, which represent an upstream end and a downstream end, respectively, of voltage control plate 620. It is appreciated that imaginary planes 625 and 626, marked as broken lines, are visual aids for illustrative purposes only. Imaginary plane 625, located closer to objective lens (e.g., objective lens 407 of FIG. 4), may define the upper boundary of cavity 628, and imaginary plane 626, located closer to sample (e.g., sample 415 of FIG. 4), may define the lower boundary of cavity 628 of voltage control plate 620. As used herein, the “cavity” of the voltage control plate refers to space defined by the aperture 622 and elongated portion 624 of voltage control plate 620 configured to allow passage of the primary electron beam 600B1, wherein the space is rotationally symmetric around primary optical axis 600-1. The term “within the cavity of voltage control plate” or “inside the cavity of voltage control plate” refers to the space bound within the imaginary planes 625 and 626 and the internal surface of opening 622 and elongated portion 624 directly exposed to primary electron beam 600B1. Imaginary planes 625 and 626 may be substantially perpendicular to primary optical axis 600-1. Although FIGS. 4, 5, 6A, 6B, and 6C illustrate a cylindrical cavity, the cross-section of cavity 628 may be cylindrical, conical, staggered cylindrical, staggered conical, or any suitable cross-section.

As illustrated in FIG. 6B, voltage control plate 620 may be formed or fabricated from a single, monolithic piece of an electrically conducting material such that horizontal portion 621 and elongated portion 624 form a continuous structure. Voltage control plate 620 may be fabricated such that the inner surface of opening 622 of horizontal portion 621 and inner surface of elongated portion 624 are substantially aligned with each other.

Alternatively, as illustrated in FIG. 6C, horizontal portion 631 and elongated portion 634 may be coupled together to form voltage control plate 630. In some embodiments, horizontal portion 631 and elongated portion 634 may be coupled using a coupling mechanism such as, but not limited to, welding, gluing, bonding, brazing, or hardware assembly, or other suitable mechanisms. Voltage control plate 630 may be fabricated, formed, or assembled such that the inner surface of opening 632 of horizontal portion 631 and inner surface of elongated portion 634 are substantially aligned with each other. It is appreciated that horizontal portion 631 and elongated portion 634 may be formed from the same material to avoid issues associated with contact resistance, mismatched thermal coefficient, dissimilar electrical conductivity, among other things.

Turning back to FIG. 4, voltage control plate 420 of apparatus 400 may comprise a monolithic voltage control plate (e.g., voltage control plate 620 of FIG. 6B) or a coupled voltage control plate (e.g., voltage control plate 630 of FIG. 6C). Primary electron beam 400B1 may comprise a high landing-energy electron beam. Voltage control plate 420 may be located between objective lens 407 and backscattered electron detector 413. In some embodiments, voltage control plate 420 may be located between polepiece 407P of objective lens 407 and backscattered electron detector 413. Voltage control plate 420 may be positioned upstream from backscattered electron detector 413 such that the elongated portion (e.g., elongated portion 624 of FIG. 6B or elongated portion 634 of FIG. 6C) extends downward into the space defined by the central hole of backscattered electron detector 413. The diameter d1 of the central hole of backscattered electron detector 413 may be slightly larger than an outer diameter of the elongated portion of voltage control plate 420. The central hole of backscattered electron detector 413 and a center of the opening (e.g., opening 622 of FIG. 6B) of voltage control plate 420 may be aligned with primary optical axis 400-1.

In practice, voltage control plate 420 and backscattered electron detector 413 may be electrically isolated from each other. In some embodiments, diameter d1 of the central hole of backscattered electron detector 413 may be sufficiently larger than the outer diameter of the elongated portion of voltage control plate 420 to provide electrical isolation. Additionally, or alternatively, a portion of the outer surface of backscattered electron detector 413 may be coated with an electrically insulating material to provide electrical isolation between voltage control plate 420 and backscattered electron detector 413. In some embodiments, a portion of a non-detecting surface of backscattered electron detector 413 may be coated with an insulating material. In some embodiments, the entirety of non-detecting surface of backscattered electron detector 413 may be coated with an insulating material. Voltage control plate 420 may be disposed on an insulator-coated portion of the surface of backscattered electron detector 413. The insulating materials for coating a surface of backscattered electron detector 413 may include, but are not limited to, a dielectric, a ceramic, a glass, or other suitable insulating materials. In some embodiments, however, voltage control plate 420 may not be disposed on an insulator-coated surface of backscattered electron detector 413, but instead, may be mounted on or coupled with objective lens 407. In some embodiments, voltage control plate 420 may be a stand-alone structure, neither disposed on backscattered electron detector 413 nor coupled with objective lens 407. In such a configuration voltage control plate 420 may be held in place by attaching voltage control plate 420 to a frame of apparatus 400, or any suitable holding mechanism such that voltage control plate 420 is coaxial with primary optical axis 400-1.

Apparatus 400 may comprise voltage control plate 420 configured to adjust a focal length of primary electron beam 400B1 to be incident on the sample. Voltage control plate 420 may comprise a conducting plate electrically isolated from backscattered electron detector 413. The electrical isolation may allow application of a voltage signal to voltage control plate 420 without impacting the landing energy of backscattered electrons on backscattered electron detector 413, among other things. Adding voltage control plate 420 between objective lens 407 and backscattered electron detector 413 may have numerous advantages over the existing focus correction techniques in charged-particle beam apparatuses. A voltage control plate, also referred to herein as a conducting plate or an aperture plate, may have some or all of the advantages discussed herein, among others.
i. Independent control of focal length—A voltage control plate (e.g., voltage control plate 420), the voltage to which may be independently applied or adjusted, as illustrated in FIGS. 4 and 5, may allow controlling the focal length of the primary electron beam without impacting the gain of a signal electron detector (e.g., backscattered electron detector 413 of FIG. 4) or affecting the landing energy of backscattered electrons on the backscattered electron detector.
ii. Small focus adjustment voltages—The inner diameter of the opening (e.g., opening 622 of FIG. 6B) and the cavity (e.g., cavity 628 of FIG. 6B) is smaller than the inner diameter of the backscattered electron detector but large enough to allow the primary and the secondary electron beams to pass through. Because of its small inner diameter, small applied voltage signals to the voltage control plate may cause appreciable adjustment of focal lengths of the primary electron beam passing therethrough. As an example, the focal length of the primary electron beam may be adjusted by up to 10 μm by applying a voltage signal less than 100V.
iii. Large range of focal lengths—Because the inner diameter of the aperture of the voltage control plate is small, the focusing power per unit voltage applied may be large. This may allow obtaining a larger range of focal lengths by applying small voltage signals.
iv. Improved safety—The voltage control plate, when positioned between the objective lens and the backscattered electron detector, may block stray electrons (primary or secondary) and substantially prevent exposure of the back-surface or hardware including wires associated with backscattered electron detector to the stray electrons. Blocking the stray electrons from being incident on the back-surface of the backscattered electron detector may minimize the risk of potential electrical or mechanical failures, or undesirable charge build-up.
v. Improved reliability—Extended use of the inspection apparatus may cause a build-up of contaminants, debris, or charges on surfaces exposed to the primary or secondary electrons. The build-up of charges or contaminants on the inner surfaces of the central hole of the backscattered electron detector may impact the rotational symmetry and smoothness, which may induce higher order electric fields such as quadrupole fields. The higher order fields may interfere with the electrostatic field experienced by the primary electron beam and may negatively affect the probe spot size or probe spot shape. Although the inner surface of the backscattered electron detector may be cleaned, polishing the inner surface to maintain the smoothness may be challenging. In comparison, it may be easier to polish or clean the inner surface of the voltage control plate which is made from a metal, thereby allowing obtaining high quality images reliably while maintaining the throughput.
vi. Improved stability—In metrology applications, the stability of overall magnification of an electron optical system may determine the stability and minimize the effort spent on calibrating the charged-particle system. Adjustment of the small voltages applied to the voltage control plate to adjust the focal length of the primary electron beam may not impact the overall magnification of the electron optical system. This is because the voltage control plate may be located close to the sample and therefore, the voltages required to adjust the focusing power of the voltage control plate may be small, which may not negatively affect the overall magnification of the lenses of the electron optical system.
vii. Design flexibility—The concentricity of the voltage control plate, the backscattered electron detector, a control electrode (e.g., control electrode 414 of FIG. 4), or objective lens may be controlled during the assembly process or may be adjusted by a suitable mechanism to avoid tolerance-induced deflection fields, which may negatively impact the probe spot characteristics.

In charged-particle beam inspection systems, such as a SEM, one of several ways to adjust the image resolution may include adjusting a working distance of the objective lens, among other things. In this context, working distance refers to the distance between the polepiece (e.g., polepiece 407P of FIG. 4) and a surface of the sample (e.g., sample 415 of FIG. 4). A higher image resolution may be obtained by reducing the working distance of the objective lens. However, in high landing-energy beam systems using a backscattered electron detector for inspection of 3D structures, reducing the working distance to obtain higher resolution may render the tool inadequate due to throughput limitations, focusing power limitations, detector collection efficiency limitations, or physical space constraints, among other things. For inspection or metrology applications, it may be beneficial to obtain high resolution images while maintaining the throughput and accuracy with respect to measurements of features or defect detection during wafer inspection.

FIG. 4 illustrates a schematic diagram of apparatus 400 configured to image a sample using high landing-energy charged-particle beam 400B1, consistent with embodiments of the present disclosure. Apparatus 400 may be configured to image sample 415 with fast focus-correction using voltage control plate 420, with higher throughput and higher signal electron detection efficiency.

As illustrated in FIG. 4, the elongated portion (e.g., elongated portion 624 of FIG. 6B) of voltage control plate 420 may extend downward into the central hole of backscattered electron detector 413 such that the downstream end of the elongated portion of voltage control plate 420 aligns with horizontal plane 413P along which backscattered electron detector 413 extends. In such a configuration, the diameter d1 of central hole of backscattered electron detector 413 may be small, enabling a higher backscattered electron collection efficiency by collecting backscattered electrons over a large range of emission angles and emission energies. In apparatus 400, the working distance (WD1) between polepiece 407P and sample 415 may be increased to accommodate voltage control plate 420. This configuration may be useful in applications where higher throughput and higher BSE detector collection efficiency are desirable, while maintaining high quality of images and measurement accuracy. It is appreciated that while the diameter of central hole of backscattered electron detector 413 may be smaller, it may be large enough to allow primary electron beam 400B1 and secondary electron beam 400B4 to pass through, unhindered.

Reference is now made to FIG. 5, which illustrates a schematic diagram of a portion of an exemplary charged-particle beam apparatus 500, consistent with embodiments of the present disclosure. Apparatus 500 may be configured to image sample 515 with fast focus-correction using a voltage control plate 520.

In some embodiments, apparatus 500 may include an objective lens 507 configured to focus primary electron beam 500B1 on a surface of sample 515, a voltage control plate 520 configured to receive an electrical signal from voltage control unit 525, a backscattered electron detector 513 configured to detect signal electron beam 500B2, a control electrode 514, secondary electron detector 506 configured to detect signal electron beam 500B4, a controller 50 (analogous to controller 50 of FIGS. 2 and 3). It is appreciated that, although not illustrated, apparatus 500 may include other components, as appropriate.

Voltage control plate 520 of apparatus 500 may comprise a monolithic voltage control plate (e.g., voltage control plate 620 of FIG. 6B) or a coupled voltage control plate (e.g., voltage control plate 630 of FIG. 6C). In some embodiments, voltage control plate 520 may be configured to adjust a focal length of primary electron beam 500B1 to be incident on sample 515. Primary electron beam 500B1 may comprise a high landing-energy electron beam.

As illustrated in FIG. 5, the elongated portion (e.g., elongated portion 624 of FIG. 6B) of voltage control plate 520 may extend downward into the central hole of backscattered electron detector 513 such that the downstream end of the elongated portion of voltage control plate 520 extends beyond horizontal plane 513P. Plane 513P, analogous to plane 413P, represents a central plane of backscattered electron detector 513 with respect to a thickness of backscattered electron detector 513 in a direction parallel to primary optical axis 500-1. In such a configuration, the diameter d2 of central hole of backscattered electron detector 513 may be larger in comparison with diameter d1 of backscattered electron detector 413 to accommodate voltage control plate 520 while maintaining electrical isolation. In apparatus 500, the working distance (WD2) between polepiece 507P and sample 515, may be shorter compared to WD1, which may enable obtaining images with high resolution. This configuration may be useful in applications where higher resolution of images is desirable, while maintaining high throughput and measurement accuracy. The electron collection efficiency of backscattered electron detector 513 may be lower compared to the electron collection efficiency of backscattered electron detector 413.

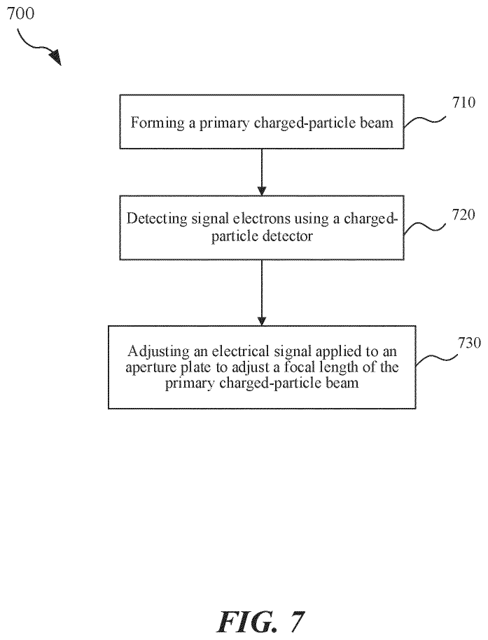

Reference is now made to FIG. 7, which illustrates a process flowchart representing an exemplary method 700 of imaging a sample, consistent with embodiments of the present disclosure. One or more steps of method 700 may be performed by controller 50 of EBI system 100, as shown in FIG. 2, for example. For example, controller 50 may instruct a module of a charged particle beam apparatus to activate a charged-particle source to generate primary charged particle beam (e.g., electron beam), apply electrical signals to voltage control plate, and carry out other functions.

In step 710, a charged-particle source is activated to emit charged particles. The charged particles may pass through an aperture to form a charged-particle beam (e.g., primary charged-particle beam 400B1 of FIG. 4 or primary charged-particle beam 500B1 of FIG. 5). The electron source may be activated by a controller (e.g., controller 50 of FIG. 3). For example, the electron source may be controlled to emit primary electrons to form an electron beam along a primary optical axis (e.g., primary optical axis 400-1 of FIG. 4 or primary optical axis 500-1 of FIG. 5). The electron source may be activated remotely, for example, by using a software, an application, or a set of instructions for a processor of a controller to power the electron source through a control circuitry. The primary electron beam may pass through a Coulomb aperture array (e.g., Coulomb aperture array 224 of FIG. 2) and a beam-limit aperture array (e.g., beam-limit aperture array 305 of FIG. 3) to adjust the beam size or beam current of the primary electron beam and form a probing beam incident on a sample (e.g., sample 415 of FIG. 4 or sample 515 of FIG. 5).

In step 720, a signal electron detector (e.g., backscattered electron detector 413 of FIG. 4 or backscattered electron detector 513 of FIG. 5) may detect signal electrons (e.g., backscattered electron beam 400B2 of FIG. 4 or backscattered electron beam 500B2 of FIG. 5). Backscattered electrons (BSEs) may be generated by elastic scattering events of the incident electrons from the underlying deeper layers, such as bottom surfaces of deep trenches or high aspect-ratio holes and have high emission energy—between 50 eV and incident energy of primary electron beam. The backscattered electron detector may be located between the sample and the objective lens. The diameter of the central hole of the backscattered electron detector may be varied based on the desired collection efficiency. For example, a smaller diameter of the central hole of the backscattered electron detector may enable collection of BSEs having a broader range of emission angles and emission energies.

The charged-particle beam apparatus (e.g., apparatus 400 of FIG. 4 or apparatus 500 of FIG. 5) may include a voltage control plate (e.g., voltage control plate 420 of FIG. 4 or voltage control plate 520 of FIG. 5) configured to receive an electrical signal. The electrical signal may be a voltage signal applied by a voltage control unit (e.g., voltage control unit 425 of FIG. 4 or voltage control unit 525 of FIG. 5). The voltage control plate may comprise an electrically conducting plate made from a conducting material such as a metal. In some embodiments, voltage control plate may be made from a non-magnetic material.

In step 730, the voltage control unit may adjust the applied voltage signal to the voltage control plate to adjust the electrostatic field experienced by the primary electron beam passing through a cavity (e.g., cavity 628 of FIG. 6B). The change in electrostatic field may influence the focal length of the primary electron beam passing through to be incident on the sample. The voltage control plate is a separate element, the voltage to which may be independently applied and controlled without impacting the landing energy of the backscattered electrons on the backscattered electron detector. The voltage control plate and the backscattered electron detector may be electrically isolated from each other.

A non-transitory computer readable medium may be provided that stores instructions for a processor of a controller (e.g., controller 50 of FIG. 1) to carry out image inspection, image acquisition, activating charged-particle source, adjusting electrical excitation of stigmators, adjusting landing energy of electrons, adjusting objective lens excitation, applying an electrical signal to a voltage control plate to vary the electrostatic field experienced by a primary electron beam, adjusting the electrical signal to adjust the focal length of the primary electron beam, stage motion control, activating a beam deflector to deflect primary electron beam, applying electrical excitation signals including AC voltage, etc. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments of the present disclosure may further be described using the following clauses:

1. A charged-particle beam apparatus comprising:
a charged-particle source configured to emit charged particles, the emitted charged particles forming a primary charged-particle beam along a primary optical axis;
an objective lens comprising a magnetic lens;
a charged-particle detector located downstream from the objective lens with respect to a path of the primary charged-particle beam and along a horizontal plane substantially perpendicular to the primary optical axis; and
a voltage control plate located between the charged-particle detector and a polepiece of the magnetic lens, the voltage control plate comprising:
a horizontal portion comprising an opening; and
an elongated portion extending downward from the opening with respect to the path of the primary charged-particle beam, into a hole of the charged-particle detector.

2. The apparatus of clause 1, wherein the elongated portion comprises an inner diameter that is substantially similar to a diameter of the opening of the horizontal portion.

3. The apparatus of clause 2, wherein the diameter of the opening is smaller than a diameter of the hole of the charged-particle detector.

4. The apparatus of any one of clauses 1-3, wherein the opening and the elongated portion form a cavity configured to allow the primary charged-particle beam to pass through.

5. The apparatus of clause 4, wherein the cavity comprises a cylindrical cavity rotationally symmetric around the primary optical axis.

6. The apparatus of any one of clauses 4 and 5, wherein an inner surface of the elongated portion and an inner surface of the opening forming the cavity are aligned with each other.

7. The apparatus of any one of clauses 4-6, further comprising a controller including circuitry configured to:
apply an electrical signal to the voltage control plate; and
adjust the electrical signal to influence an electrostatic field experienced by the primary charged-particle beam passing through the cavity, wherein the electrical signal comprises a voltage signal.

8. The apparatus of clause 7, wherein adjustment of the electrical signal is configured to cause the voltage control plate to adjust a focal length of the primary charged-particle beam to be incident on a sample.

9. The apparatus of any one of clauses 7 and 8, wherein the applied voltage signal of 100 V or less causes the adjustment of the focal length of the primary charged-particle beam by up to 10 μm.

10. The apparatus of any one of clauses 1-9, wherein the charged-particle detector and the voltage control plate are electrically isolated from each other.

11. The apparatus of any one of clauses 1-10, wherein a downstream end of the elongated portion extends into the hole of the charged-particle detector and beyond the horizontal plane along which the charged-particle detector extends, the horizontal plane comprising a central plane with respect to a thickness of the charged-particle detector.

12. The apparatus of any one of clauses 1-10, wherein a downstream end of the elongated portion extends into the hole of the charged-particle detector and substantially aligns with the horizontal plane along which the charged-particle detector extends, the horizontal plane comprising a central plane with respect to a thickness of the charged-particle detector.

13. The apparatus of any one of clauses 1-12, further comprising a control electrode located downstream from the charged-particle detector.

14. The apparatus of clause 13, wherein the voltage control plate, the charged-particle detector, the control electrode, and the objective lens are coaxial.

15. The apparatus of any one of clauses 1-14, wherein the voltage control plate comprises an electrically conducting plate.

16. The apparatus of any one of clauses 1-15, wherein the horizontal portion of the voltage control plate is formed from a monolithic substrate.

17. The apparatus of any one of clauses 1-16, wherein the horizontal portion of the voltage control plate is formed by coupling two or more plates.

18. The apparatus of any one of clauses 1-17, wherein the elongated portion is fluidly connected with the horizontal portion of the voltage control plate.

19. The apparatus of any one of clauses 1-18, wherein the elongated portion is coupled with the horizontal portion using a hardware assembly, welding, gluing, bonding, or brazing.

20. The apparatus of any one of clauses 1-19, wherein the charged-particle detector comprises a backscattered electron detector configured to detect backscattered electrons.

21. The apparatus of any one of clauses 3-20, wherein the elongated portion comprises an outer diameter, and wherein the outer diameter is smaller than the diameter of the hole of the charged-particle detector.

22. The apparatus of any one of clauses 6-21, wherein the inner surface of the elongated portion and the inner surface of the opening are configurable to provide a superior surface in comparison to an inner surface of the hole of the charged-particle detector.

23. The apparatus of any one of clauses 6-22, wherein the inner surface of the elongated portion and the inner surface of the opening are configurable to maintain an ellipticity of the cavity.

24. The apparatus of clause 23, wherein the ellipticity of the cavity allows the primary charged-particle beam to pass through the cavity substantially undeflected.

25. The apparatus of any one of clauses 1-24, wherein the voltage control plate comprises a non-magnetic material.

26. A method for imaging a sample using a charged-particle beam apparatus, the method comprising:
forming a primary charged-particle beam from charged particles emitted by a charged-particle source;
detecting, using a charged-particle detector, signal electrons generated from the sample upon interaction of the primary charged-particle beam with the sample; and
adjusting an electrical signal applied to a voltage control plate, wherein the voltage control plate comprises:
a horizontal portion comprising an opening; and
an elongated portion extending downward from the opening with respect to a path of the primary charged-particle beam, into a hole of the charged-particle detector.

27. The method of clause 26, wherein the voltage control plate is located between the charged-particle detector and a polepiece of an objective lens.

28. The method of any one of clauses 26 and 27, wherein the elongated portion comprises an inner surface that is substantially similar to a diameter of the opening of the horizontal portion.

29. The method of clause 28, wherein the diameter of the opening is smaller than a diameter of the hole of the charged-particle detector.

30. The method of any one of clauses 26-29, wherein the opening and the elongated portion form a cavity configured to allow the primary charged-particle beam to pass through.

31. The method of clause 30, wherein the cavity comprises a cylindrical cavity rotationally symmetric around the primary optical axis.

32. The method of any one of clauses 30 and 31, wherein an inner surface of the elongated portion and an inner surface of the opening are aligned with each other.

33. The method of any one of clauses 30-32, further comprising:
applying a voltage signal to the voltage control plate; and
adjusting the voltage signal to influence an electrostatic field experienced by the primary charged-particle beam passing through the cavity.

34. The method of clause 33, wherein adjusting the voltage signal causes an adjustment of a focal length of the primary charged-particle beam to be incident on the sample.

35. The method of clause 34, wherein adjusting the voltage signal by 100 V or less adjusts the focal length of the primary charged-particle beam by up to 10 μm.

36. The method of any one of clauses 26-35, wherein the voltage control plate and the charged-particle detector are electrically isolated from each other.

37. The method of clause 36, wherein electrically isolating the voltage control plate and the charged-particle detector comprises forming an electrically insulating layer on a non-detecting surface of the charged-particle detector.

38. The method of any one of clauses 26-37, wherein a downstream end of the elongated portion extends into the hole of the charged-particle detector and beyond the horizontal plane along which the charged-particle detector extends, the horizontal plane comprising a central plane with respect to a thickness of the charged-particle detector.

39. The method of any one of clauses 26-37, wherein a downstream end of the elongated portion extends into the hole of the charged-particle detector and substantially aligns with a horizontal plane along which the charged-particle detector extends, the horizontal plane comprising a central plane with respect to a thickness of the charged-particle detector.

40. The method of any one of clauses 26-39, wherein the voltage control plate and the charged-particle detector are aligned with the primary optical axis.

41. The method of any one of clauses 26-40, wherein the voltage control plate comprises an electrically conducting plate.

42. The method of any one of clauses 26-41, wherein the horizontal portion of the voltage control plate is formed from a monolithic substrate.

43. The method of any one of clauses 26-42, wherein the horizontal portion is formed by coupling two or more plates.

44. The method of any one of clauses 26-43, wherein the elongated portion is fluidly connected with the horizontal portion of the voltage control plate.

45. The method of any one of clauses 26-44, wherein the elongated portion is coupled with the horizontal portion using a hardware assembly, welding, gluing, bonding, or brazing.

46. The method of any one of clauses 26-45, wherein the charged-particle detector comprises a backscattered electron detector configured to detect backscattered electrons.

47. The method of any one of clauses 26-46, wherein the elongated portion comprises an outer diameter, the outer diameter is smaller than the diameter of the hole of the charged-particle detector.

48. The method of any one of clauses 32-47, further comprising modifying the inner surface of the elongated portion and the inner surface of the opening to provide a superior surface in comparison to an inner surface of the hole of the charged-particle detector.

49. The method of clause 48, wherein modifying comprises cleaning, polishing, or reworking the inner surface of the elongated portion and the inner surface of the opening to maintain an ellipticity of the cavity.

50. The method of clause 49, wherein maintaining the ellipticity of the cavity allows the primary charged-particle beam to pass through the cavity substantially undeflected.

51. The method of any one of clauses 26-50, wherein the voltage control plate comprises a non-magnetic material.

52. A non-transitory computer readable medium storing a set of instructions that is executable by one or more processors of a charged-particle beam apparatus to cause the charged-particle beam apparatus to perform a method, the method comprising:
acquiring signals from a charged-particle detector, wherein the signals result from the charged-particle detector detecting signal electrons generated from a sample upon interaction of a primary charged-particle beam with the sample; and
adjusting an electrical signal applied to a voltage control plate to enable adjusting a focal length of the primary charged-particle beam to be incident on the sample, wherein the voltage control plate comprises:
a horizontal portion comprising an opening; and
an elongated portion extending downward from the opening with respect to a path of the primary charged-particle beam, into a hole of the charged-particle detector.

53. The non-transitory computer readable medium of clause 52, wherein the opening and the elongated portion form a cavity configured to allow the primary charged-particle beam to pass through.

54. The non-transitory computer readable medium of clause 53, wherein the set of instructions that is executable by the one or more processors of the charged-particle beam apparatus causes the charged-particle beam apparatus to further perform:
applying a voltage signal to the voltage control plate; and
adjusting the voltage signal to influence an electrostatic field experienced by the primary charged-particle beam passing through the cavity.

55. The non-transitory computer readable medium of clause 54, wherein adjusting the voltage signal causes an adjustment of a focal length of the primary charged-particle beam to be incident on the sample.

56. The non-transitory computer readable medium of clause 55, wherein adjusting the voltage signal by 100 V or less adjusts the focal length of the primary charged-particle beam by up to 10 μm.

57. The non-transitory computer readable medium of any one of clauses 52-56, wherein the voltage control plate and the charged-particle detector are electrically isolated from each other.

58. The non-transitory computer readable medium of clause 57, wherein electrically isolating the voltage control plate and the charged-particle detector comprises forming an electrically insulating layer on a non-detecting surface of the charged-particle detector.

59. The non-transitory computer readable medium of any one of clauses 52-58, wherein a downstream end of the elongated portion extends into the hole of the charged-particle detector and beyond the horizontal plane along which the charged-particle detector extends, the horizontal plane comprising a central plane with respect to a thickness of the charged-particle detector.

60. The non-transitory computer readable medium of any one of clauses 52-58, wherein a downstream end of the elongated portion extends into the hole of the charged-particle detector and substantially aligns with a horizontal plane along which the charged-particle detector extends, the horizontal plane comprising a central plane with respect to a thickness of the charged-particle detector.

61. An electron-optical assembly comprising:
an objective lens comprising a magnetic lens;
a charged-particle detector located downstream from the objective lens with respect to a path of a primary charged-particle beam and along a horizontal plane substantially perpendicular to a primary optical axis; and
a voltage control plate located between the charged-particle detector and a polepiece of the magnetic lens, the voltage control plate comprising:
a horizontal portion comprising an opening; and
an elongated portion extending downward from the opening with respect to the path of the primary charged-particle beam, into a hole of the charged-particle detector,
wherein the opening and the elongated portion form a cavity configured to allow the primary charged-particle beam to pass through.

62. The assembly of clause 61, wherein the elongated portion comprises an inner diameter that is substantially similar to a diameter of the opening of the horizontal portion.

63. The assembly of clause 62, wherein the diameter of the opening is smaller than a diameter of the hole of the charged-particle detector.

64. The assembly of any one of clauses 61-63, wherein the cavity comprises a cylindrical cavity rotationally symmetric around the primary optical axis.

65. The assembly of any one of clauses 61-64, wherein an inner surface of the elongated portion and an inner surface of the opening forming the cavity are aligned with each other.

66. The assembly of any one of clauses 61-65, further comprising a controller including circuitry configured to:
apply an electrical signal to the voltage control plate; and
adjust the electrical signal to influence an electrostatic field experienced by the primary charged-particle beam passing through the cavity, wherein the electrical signal comprises a voltage signal.

67. The assembly of clause 66, wherein adjustment of the electrical signal is configured to cause the voltage control plate to adjust a focal length of the primary charged-particle beam to be incident on a sample.

68. The assembly of any one of clauses 66 and 67, wherein the applied voltage signal of 100 V or less causes the adjustment of the focal length of the primary charged-particle beam by up to 10 μm.

69. The assembly of any one of clauses 61-68, wherein the charged-particle detector and the voltage control plate are electrically isolated from each other.

70. The assembly of any one of clauses 61-69, wherein a downstream end of the elongated portion extends into the hole of the charged-particle detector and beyond the horizontal plane along which the charged-particle detector extends, the horizontal plane comprising a central plane with respect to a thickness of the charged-particle detector.

71. The assembly of any one of clauses 61-69, wherein a downstream end of the elongated portion extends into the hole of the charged-particle detector and substantially aligns with the horizontal plane along which the charged-particle detector extends, the horizontal plane comprising a central plane with respect to a thickness of the charged-particle detector.

72. The assembly of any one of clauses 61-71, further comprising a control electrode located downstream from the charged-particle detector.

73. The assembly of clause 72, wherein the voltage control plate, the charged-particle detector, the control electrode, and the objective lens are coaxial.

74. The assembly of any one of clauses 61-73, wherein the voltage control plate comprises an electrically conducting plate.

75. The assembly of any one of clauses 61-74, wherein the horizontal portion of the voltage control plate is formed from a monolithic substrate.

76. The assembly of any one of clauses 61-74, wherein the horizontal portion of the voltage control plate is formed by coupling two or more plates.

77. The assembly of any one of clauses 61-76, wherein the elongated portion is fluidly connected with the horizontal portion of the voltage control plate.

78. The assembly of any one of clauses 61-76, wherein the elongated portion is coupled with the horizontal portion using a hardware assembly, welding, gluing, bonding, or brazing.

79. The assembly of any one of clauses 61-78, wherein the charged-particle detector comprises a backscattered electron detector configured to detect backscattered electrons.

80. The assembly of any one of clauses 63-79, wherein the elongated portion comprises an outer diameter, the outer diameter is smaller than the diameter of the hole of the charged-particle detector.

81. The assembly of any one of clauses 65-80, wherein the inner surface of the elongated portion and the inner surface of the opening are configurable to provide a superior surface in comparison to an inner surface of the hole of the charged-particle detector.

82. The assembly of any one of clauses 65-81, wherein the inner surface of the elongated portion and the inner surface of the opening are configurable to maintain an ellipticity of the cavity.

83. The assembly of clause 82, wherein the ellipticity of the cavity allows the primary charged-particle beam to pass through the cavity substantially undeflected.

84. The assembly of any one of clauses 61-83, wherein the voltage control plate comprises a non-magnetic material.

85. A plate insertable between a charged-particle detector and a polepiece of an objective lens of a charged-particle beam apparatus, the plate comprising:
a horizontal portion comprising an opening; and
an elongated portion extending downward from the opening with respect to a path of a primary charged-particle beam, into a hole of the charged-particle detector,
wherein the opening and the elongated portion form a cavity configured to allow the primary charged-particle beam to pass through.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A charged-particle beam apparatus comprising:
a charged-particle source configured to emit charged particles, the emitted charged particles forming a primary charged-particle beam along a primary optical axis;
an objective lens comprising a magnetic lens;
a charged-particle detector located downstream from the objective lens with respect to a path of the primary charged-particle beam and along a horizontal plane substantially perpendicular to the primary optical axis; and
a voltage control plate located between the charged-particle detector and a polepiece of the magnetic lens, the voltage control plate comprising:
a horizontal portion comprising an opening; and
an elongated portion extending downward from the opening with respect to the path of the primary charged-particle beam, into a hole of the charged-particle detector.

2. The apparatus of claim 1, wherein the elongated portion comprises an inner diameter that is substantially similar to a diameter of the opening of the horizontal portion.

3. The apparatus of claim 2, wherein the diameter of the opening is smaller than a diameter of the hole of the charged-particle detector.

4. The apparatus of claim 1, wherein the opening and the elongated portion form a cavity configured to allow the primary charged-particle beam to pass through.

5. The apparatus of claim 4, wherein the cavity comprises a cylindrical cavity rotationally symmetric around the primary optical axis.

6. The apparatus of claim 5, wherein an inner surface of the elongated portion and an inner surface of the opening forming the cavity are aligned with each other.

7. The apparatus of claim 5, further comprising a controller including circuitry configured to:
apply an electrical signal to the voltage control plate; and
adjust the electrical signal to influence an electrostatic field experienced by the primary charged-particle beam passing through the cavity, wherein the electrical signal comprises a voltage signal.

8. The apparatus of claim 7, wherein adjustment of the electrical signal is configured to cause the voltage control plate to adjust a focal length of the primary charged-particle beam to be incident on a sample.

9. The apparatus of claim 7, wherein the applied electrical signal of 100 V or less causes the adjustment of a focal length of the primary charged-particle beam by up to 10 μm.

10. The apparatus of claim 1, wherein the charged-particle detector and the voltage control plate are electrically isolated from each other.

11. The apparatus of claim 1, wherein a downstream end of the elongated portion extends into the hole of the charged-particle detector and beyond the horizontal plane along which the charged-particle detector extends, the horizontal plane comprising a central plane with respect to a thickness of the charged-particle detector.

12. The apparatus of claim 1, wherein a downstream end of the elongated portion extends into the hole of the charged-particle detector and substantially aligns with the horizontal plane along which the charged-particle detector extends, the horizontal plane comprising a central plane with respect to a thickness of the charged-particle detector.

13. The apparatus of claim 3, wherein the elongated portion comprises an outer diameter, and wherein the outer diameter is smaller than the diameter of the hole of the charged-particle detector.

14. The apparatus of claim 6, wherein the inner surface of the elongated portion and the inner surface of the opening are configurable to provide a superior surface in comparison to an inner surface of the hole of the charged-particle detector.

15. (canceled)

16. A non-transitory computer readable medium storing a set of instructions that is executable by one or more processors of a charged-particle beam apparatus to cause the charged-particle beam apparatus to perform operations comprising:
acquiring signals from a charged-particle detector, wherein the signals result from the charged-particle detector detecting signal electrons generated from a sample upon interaction of a primary charged-particle beam with the sample; and
adjusting an electrical signal applied to a voltage control plate to enable adjusting a focal length of the primary charged-particle beam to be incident on the sample, wherein the voltage control plate comprises:
a horizontal portion comprising an opening; and
an elongated portion extending downward from the opening with respect to a path of the primary charged-particle beam, into a hole of the charged-particle detector.

17. The non-transitory computer readable medium of claim 16, wherein the opening and the elongated portion form a cavity configured to allow the primary charged-particle beam to pass through.

18. The non-transitory computer readable medium of claim 17, wherein the operations further comprise:
applying a voltage signal to the voltage control plate; and
adjusting the voltage signal to influence an electrostatic field experienced by the primary charged-particle beam passing through the cavity.

19. The non-transitory computer readable medium of claim 18, wherein adjusting the voltage signal causes an adjustment of a focal length of the primary charged-particle beam to be incident on the sample.

20. The non-transitory computer readable medium of claim 19, wherein adjusting the voltage signal by 100 V or less adjusts the focal length of the primary charged-particle beam by up to 10 μm.

21. A plate insertable between a charged-particle detector and a polepiece of an objective lens of a charged-particle beam apparatus, the plate comprising:
a horizontal portion comprising an opening; and
an elongated portion extending downward from the opening with respect to a path of a primary charged-particle beam, into a hole of the charged-particle detector,
wherein the opening and the elongated portion form a cavity configured to allow the primary charged-particle beam to pass through.
